(19) United States
(12) Patent Application Publication
(10) Pub. No.: US 2013/0100631 A1
(43) Pub. Date: Apr. 25, 2013

(54) ELECTRONIC DEVICE WITH SUPPORTING APPARATUS

(71) Applicants: TING GE, Shenzhen City (CN); LI-REN FU, Shenzhen City (CN)

(72) Inventors: TING GE, Shenzhen City (CN); LI-REN FU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/315,295

(22) Filed: Dec. 9, 2011

(30) Foreign Application Priority Data
Oct. 25, 2011 (CN) 201110327511.0

(51) Int. Cl. H05K 7/00; H05K 7/18

(52) U.S. Cl. 361/807; 211/26

(57) ABSTRACT

A supporting apparatus for supporting a casing of an electronic device includes a supporting member and a locating member. The supporting member includes a supporting block supporting a bottom of the casing, and an extending block extending up from an end of the supporting block. The locating member is fixed to the extending block and to be detachably fixed to a sidewall of the electronic device.

### BACKGROUND

1. Technical Field

The present disclosure relates to an electronic device having a supporting apparatus.

2. Description of Related Art

In a server system, a plurality of servers are often installed into a cabinet. In assembly or during test, the servers are usually stacked up. Therefore, the servers cannot be moved conveniently, and the casings of the servers may be scratched because the casings are in direct contact with each other.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an exemplary embodiment of an electronic device, wherein the electronic device includes four supporting apparatus.

FIG. 2 is an enlarged view of one of the supporting apparatus of FIG. 1.

FIG. 3 is an assembled, isometric view of several electronic devices of FIG. 1 stacked up.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

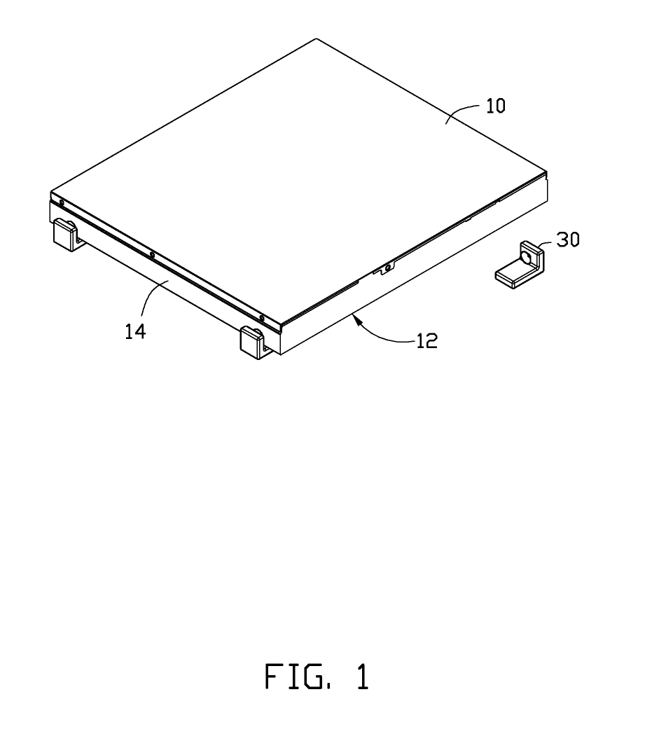

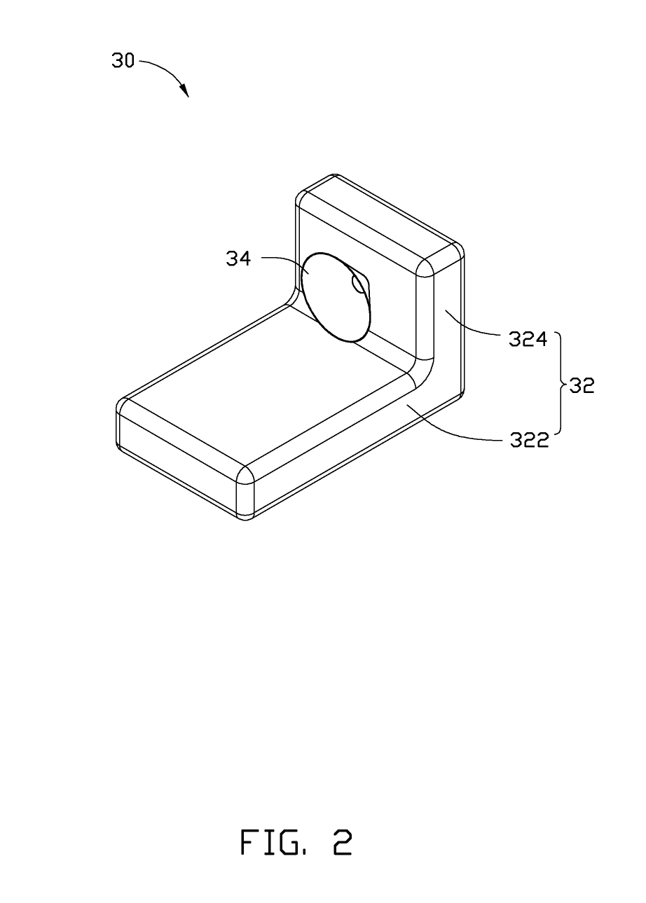

Referring to FIG. 1 and FIG. 2, an exemplary embodiment of an electronic device includes a casing 10, and a plurality of supporting apparatuses 30 for supporting the casing 10.

The casing 10 includes a bottom wall 12 and two sidewalls 14 perpendicularly extending up from two opposite sides of the bottom wall 12.

Each supporting apparatus 30 includes a substantially L-shaped supporting member 32 and a locating member 34. The supporting member 32 includes a supporting block 322 and an extending block 324 perpendicularly extending up from an end of the supporting block 322. In the embodiment, the supporting member 32 is made of resilient material, such as plastic.

In the embodiment, the locating member 34 is a suction cup fixed to the extending block 324, facing away from the extending block 324.

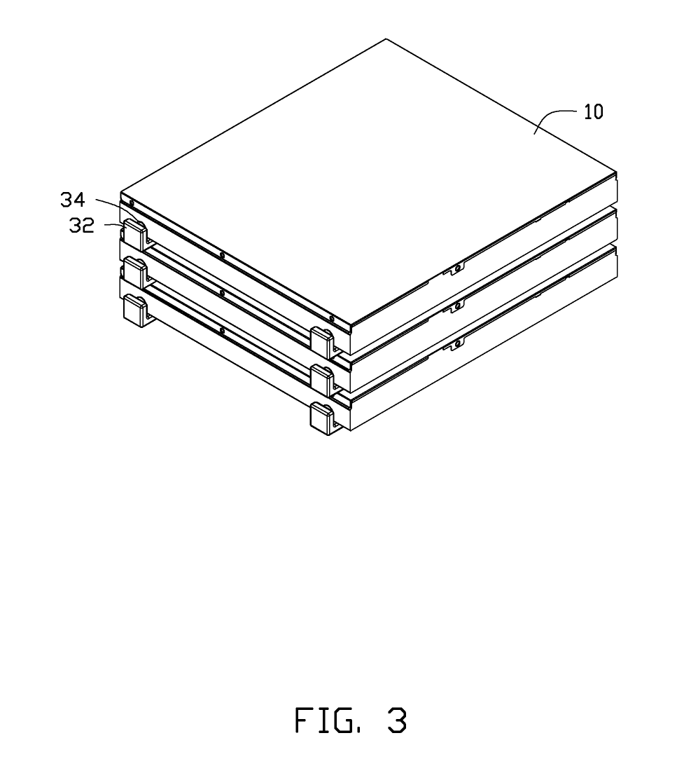

Referring to FIG. 3, in use, the bottom wall 12 of the casing 10 is supported on the supporting blocks 322. The extending blocks 324 face the corresponding sidewalls 14. The extending blocks 324 are pushed toward the corresponding sidewalls 14, until the suction cups 34 stick to the sidewalls.

When disassembling the supporting apparatus 30 from the casing 10, the extending blocks 324 are moved away from the casing 10, to allow the suction cups 34 to be detached from the corresponding sidewalls 14. The supporting apparatus 30 may be easily separated from the casing 10.

When the casing 10 is put on a table (not shown), the supporting blocks 322 are supported on the table. Therefore, the casing 10 can be spaced from the table, to avoid direct contact with the table. Furthermore, the supporting members 32 are made of resilient material, which can absorb the energy of the vibrations or shocks.

When a plurality of casings 10 are stacked up, each casing 10 is spaced from adjacent casings 10 by the supporting members 32. Thus, every two adjacent casings 10 can avoid direct contact with each other, and the adjacent casings 10 can avoid scratching each other. Furthermore, a space is defined between every two adjacent casings 10, making it convenient to allow fingers of operators to be inserted into the space to move the casings 10.

In other embodiment, the locating member 34 can be other things, such as a magnet.

It is to be understood, however, that even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A supporting apparatus for an electronic device, comprising:
a supporting member comprising a supporting block for supporting a bottom of the electronic device, and an extending block extending up from the supporting block; and
a locating member fixed to the extending block and to be detachably fixed to the electronic device.

2. The supporting apparatus of claim 1, wherein the supporting member is substantially L-shaped, the extending block perpendicularly extends up from the supporting block.

3. The supporting apparatus of claim 1, wherein the supporting member is made of resilient material.

4. The supporting apparatus of claim 1, wherein the locating member is a suction cup facing away from the extending block to suck the electronic device.

5. An electronic device comprising:
a casing comprising a bottom wall and a sidewall; and
a plurality of supporting apparatus each comprising a supporting member and a locating member, wherein the supporting member comprises a supporting block supporting the bottom of the casing, and an extending block extending up from the supporting block located at an outer side of the sidewall, the locating member fixed to the extending block and facing the sidewall and detachably fixed to the sidewall.

6. The electronic device of claim 5, wherein the supporting member is substantially L-shaped, the extending block perpendicularly extends up from the supporting block.

7. The electronic device of claim 6, wherein the locating member is a suction cup to suck the sidewall.

8. The electronic device of claim 5, wherein the supporting member is made of resilient material.
